(19) United States
(12) Patent Application Publication
(10) Pub. No.: US 2026/0109891 A1
(43) Pub. Date: Apr. 23, 2026

(54) BIODEGRADABLE DIRECT IMMERSION COOLING FLUID

(71) Applicant: TOTALENERGIES ONETECH, Courbevoie (FR)

(72) Inventors: Benjamin SWOBODA, Paris (FR); Francine GENIN, Paris (FR); Nicolas CHAMPAGNE, Solaize Cedex (FR)

(21) Appl. No.: 18/859,859

(22) PCT Filed: Apr. 24, 2023
(86) PCT No.: PCT/EP2023/060679

§ 371 Date: Jun. 28, 2025

(30) Foreign Application Priority Data
Apr. 25, 2022 (FR) FR2203806

(51) Int. Cl. C09K 5/10; H05K 7/20

(52) U.S. Cl. CPC C09K 5/10; H05K 7/20772

(57) ABSTRACT

The invention concerns the use as cooling fluid, via direct immersion, of a composition comprising 80 to 100 weight % of a hydrocarbon fluid relative to the total weight of the composition, said hydrocarbon fluid comprising at least 90 weight % of a hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%.

### TECHNICAL FIELD OF THE INVENTION

The invention concerns the use of a readily biodegradable isoparaffinic fluid as cooling fluid via direct immersion, in particular for data centers. The invention also concerns a cooling system and a cooling method via direct immersion in a readily biodegradable, isoparaffinic cooling fluid.

### PRIOR ART

Data saving is in full expansion. Many aspects of our daily lives (smart devices, homes, cities, and driverless vehicles) are dependent upon data centers which particularly comprise very numerous computers and very numerous servers. These centers are costly in terms of energy consumption.

Numerous techniques can be used to cool electronic devices (e.g. processors, memories, networking devices and other heat-generating devices) which are contained in data centers. For example, forced convection can be set up by providing a stream of cooling air above these devices. Fans positioned in the vicinity of the devices, fans positioned in the rooms of data processing servers and/or fans positioned in ducts in fluid communication with the air surrounding electronic devices, can force a flow of cooling air within data centers.

More recently, cooling systems via immersion in a cooling liquid have been developed.

Liquid cooling via single-phase direct immersion means that the cooling liquid does not undergo a phase change during the cooling process (heat dissipation) of equipment in data centers.

Cooling liquids via direct single-phase immersion have been developed. They are typically fluorocarbon compounds. These compounds are powerful greenhouse gases which can have an impact on the ozone layer (Global Warming Potential).

A further issue which the invention sets out to solve is the health and comfort of operators using the cooling liquid.

Document WO2022/038313 discloses a biobased fluid and the use thereof as cooling liquid via single-phase direct immersion. This document does not disclose the fluid as claimed herein, in particular having an aromatics content of less than 100 ppm. The high content of aromatics as disclosed by this document generates problems of irritation for persons handling the fluid.

It is the objective of the present invention to provide a biobased, readily biodegradable hydrocarbon fluid as cooling fluid via direct single-phase immersion for data centers, having a longer lifetime than fluids in the prior art and providing better safety for operators.

### SUMMARY OF THE INVENTION

The invention concerns the use as cooling fluid, via direct immersion, of a composition comprising 80 to 100 weight % of a hydrocarbon fluid relative to the total weight of the composition, said hydrocarbon fluid comprising at least 90 weight % of a hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%.

In one embodiment the hydrocarbon fluid, relative to the total weight of the hydrocarbon fluid, comprises:
at least 95 weight % of isoparaffins, and/or
at most 5 weight % of normal paraffins, and/or
at most 1 weight % of naphthenes, and/or
less than 50 ppm by weight of aromatics.

In one embodiment, the hydrocarbon fluid has:
a flash point higher than or equal to 110° C., preferably higher than or equal to 120° C., even higher than or equal to 140° C. according to standard ASTM D93, and/or
a kinematic viscosity at 40° C. lower than or equal to 5 cSt, preferably lower than or equal to 4 cSt.

In one embodiment, the hydrocarbon fluid has:
an initial boiling point and final boiling point in the range of 200 to 400° C., preferably 240 to 350° C., more preferably 250 to 340° C., and/or
a difference between the final boiling point and the initial boiling point ranging from 10° C. to 80° C., preferably from 20° C. to 50° C.

In one embodiment, the hydrocarbon fluid, relative to the total weight of the hydrocarbon fluid, comprises:
30 to 60 weight % of C15 isoparaffins and 30 to 60 weight % of C16 isoparaffins, or
5 to 15 weight % of C15 isoparaffins, 30 to 60 weight % of C16 isoparaffins, 10 to 30 weight % of C17 isoparaffins and 10 to 30 weight % of C18 isoparaffins, or
10 to 30 weight % of C17 isoparaffins and 60 to 90 weight % of C18 isoparaffins.

In one embodiment, the composition comprises 100 weight % of the cooling fluid.

In another embodiment the composition additionally comprises, relative to the total weight of the composition, from 0.01 to 20 weight % of additives preferably chosen from among antioxidants, flame retardants and mixture thereof.

In another embodiment, the composition is free of flame retardants.

The invention also concerns a cooling system via direct immersion, comprising:
a bath comprising a composition comprising from 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%;
at least one item of equipment to be cooled, partially or fully immersed in the composition.

In one embodiment of the cooling system, the item of equipment to be cooled is equipment in a data center.

In one embodiment of the cooling system, the hydrocarbon fluid comprises one or more of the following characteristics:
the hydrocarbon fluid, relative to the total weight of the hydrocarbon fluid, comprises:
   at least 95 weight % of isoparaffins, and/or
   at most 5 weight % of normal paraffins, and/or
   at most 1 weight % of naphthenes, and/or
   less than 50 ppm by weight of aromatics;
and/or the hydrocarbon fluid has:
   a flash point higher than or equal to 110° C., preferably higher than or equal to 120° C., even higher than or equal to 140° C. according to standard ASTM D93, and/or
   kinematic viscosity at 40° C. lower than or equal to 5 cSt, preferably lower than or equal to 4 cSt;
and/or the hydrocarbon fluid has:
   an initial boiling point and final boiling point in the range of 200 to 400° C., preferably 240 to 350° C., more preferably 250 to 340° C., and/or
   a difference between the final boiling point and initial boiling point ranging from 10° C. to 80° C., preferably 20° C. to 50° C.;
and/or the hydrocarbon fluid, relative to the total weight of the hydrocarbon fluid, comprises:
   30 to 60 weight % of C15 isoparaffins and 30 to 60 weight % of C16 isoparaffins, or
   5 to 15 weight % of C15 isoparaffins, 30 to 60 weight % of C16 isoparaffins, 10 to 30 weight % of C17 isoparaffins, and 10 to 30 weight % of C18 isoparaffins, or
   10 to 30 weight % of C17 isoparaffins and 60 to 90 weight % of C18 isoparaffins.

In one embodiment of the cooling system, the composition comprises 100 weight % of the cooling fluid.

In one embodiment of the cooling system, the composition additionally comprises, relative to the total weight of the composition, from 0.01 to 20 weight % of additives preferably chosen from among antioxidants, flame retardants and mixture thereof.

A further subject of the invention is a cooling method via direct immersion comprising a step of fully or partially immersing at least one item of equipment to be cooled in a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60% relative to the total weight of the carbon atoms.

In one embodiment of the cooling method, the item of equipment to be cooled is equipment in a data center.

In one embodiment of the cooling method, the item of equipment to be cooled is equipment in a data center.

In one embodiment of the cooling method, the hydrocarbon fluid has one or more of the following characteristics:
the hydrocarbon fluid, relative to the total weight of the hydrocarbon fluid, comprises:
   at least 95 weight % of isoparaffins, and/or
   at most 5 weight % of normal paraffins, and/or
   at most 1 weight % of naphthenes, and/or
   less than 50 ppm by weight of aromatics;
and/or the hydrocarbon fluid has:
   a flash point higher than or equal to 110° C., preferably higher than or equal to 120° C., even higher than or equal to 140° C. according to standard ASTM D93, and/or
   a kinematic viscosity at 40° C. lower than or equal to 5 cSt, preferably lower than or equal to 4 cSt;
and/or the hydrocarbon fluid has:
   an initial boiling point and a final boiling point in the range of 200 to 400° C., preferably 240 to 350° C., more preferably 250 to 340° C., and/or
   a difference between the final boiling point and the initial boiling point ranging from 10° C. to 80° C., preferably from 20° C. to 50° C.;
and/or the hydrocarbon fluid, relative to the total weight of the hydrocarbon fluid, comprises:
   30 to 60 weight % of C15 isoparaffins and 30 to 60 weight % of C16 isoparaffins, or
   from 5 to 15 weight % of C15 isoparaffins, 30 to 60 weight % of C16 isoparaffins, 10 to 30 weight % of C17 isoparaffins, and 10 to 30 weight % of C18 isoparaffins, or
   10 to 30 weight % of C17 isoparaffins and 60 to 90 weight % of C18 isoparaffins.

In one embodiment of the cooling method, the composition comprises 100 weight % of the cooling fluid.

In one embodiment of the cooling method, the composition additionally comprises relative to the total weight of the composition, from 0.01 to 20 weight % of additives preferably chosen from among antioxidants and flame retardants, and mixture thereof.

The invention allows to provide a cooling fluid having excellent resistance to ageing. In particular, the hydrocarbon fluid defined in the present invention has an improved lifetime compared with prior art fluids, in particular compared with fluids having a higher aromatics content.

The use as cooling fluid via immersion provides extended use of the same fluid, possibly reaching up to 5 years, even 10 years. As a result, it is advantageous that the fluid remains highly stable over time, in other words it is advantageous that it does not degrade over time.

The inventors have therefore discovered that the hydrocarbon fluid defined in the present invention is particularly stable against ageing, a stability due in particular to the low aromatics content of less than 100 ppm.

The inventors have therefore found that the hydrocarbon fluid defined in the present invention is much less irritant than fluids in the prior art, this low irritation being obtained in particular through the low content of aromatics.

### DETAILED DESCRIPTION OF THE INVENTION

The invention concerns the use as cooling fluid via direct immersion of a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability of at least 60% measured according to standard OECD 301B.

A further subject of the invention is a cooling system via direct immersion, comprising:
a bath comprising a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability of at least 60% measured according to standard OECD 301B,
at least one item of equipment to be cooled, partially or fully immersed in the hydrocarbon fluid.

Finally, a further subject of the invention is a cooling method via direct immersion comprising a step of fully or partially immersing at least one item of equipment to be cooled in a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability of at least 60% measured according to standard OECD 301B.

As a preliminary remark, it is pointed out that in the description and following claims, the expression «between» is to be construed as including the cited limits.

In the meaning of the present invention, the word «paraffins» includes isoparaffins and n-paraffins.

In the meaning of the present invention, the word «isoparaffins» designates non-cyclic branched alkanes.

In the meaning of the present invention, the word «n-paraffins» designates non-cyclic straight-chain alkanes.

In the meaning of the present invention, the word «naphthenes» designates (non-aromatic) cyclic alkanes.

### Composition:

In the invention, the composition comprises 80 to 100 weight % of a hydrocarbon fluid relative to the total weight of the composition.

In one embodiment, the composition comprises 100 weight % of the hydrocarbon fluid. In this embodiment, the hydrocarbon fluid is used as cooling fluid.

In another embodiment, the composition additionally comprises 0.01 to 20 weight % of additives chosen from among antioxidants, flame retardants and mixture thereof, relative to the total weight of the composition.

In one embodiment, the composition comprises:
85 to 99.99 weight %, preferably 90 to 99.5 weight %, more preferably 95 to 99 weight % of the hydrocarbon fluid,
0.01 to 15 weight %, preferably 0.5 to 10 weight %, more preferably 1 to 5 weight % of additives,
relative to the total weight of the composition.

In one embodiment, the composition comprises, even consists of:
at least 97 weight %, preferably at least 98 weight % of the hydrocarbon fluid,
optionally 0.01 to 3 weight %, preferably 0.05 to 2 weight % of antioxidant(s), relative to the total weight of the composition.

In one embodiment, the composition comprises:
85 to 99.99 weight %, preferably 90 to 99.5 weight %, more preferably 95 to 99 weight % of the hydrocarbon fluid,
0.01 to 15 weight %, preferably 0.5 to 10 weight %, more preferably 1 to 5 weight % of additives,
relative to the total weight of the composition,
   said composition being free of flame retardants.

### Hydrocarbon Fluid:

The hydrocarbon fluid used in the invention has a content of at least 90 weight % of isoparaffins, preferably at least 95 weight %, more preferably at least 98 weight % of isoparaffins, relative to the total weight of the hydrocarbon fluid.

The hydrocarbon fluid used in the invention has a content less than or equal to 10 weight % of normal paraffins, preferably less than or equal to 5 weight %, more preferably less than or equal to 2 weight % of normal paraffins, relative to the total weight of the hydrocarbon fluid.

Preferably, the hydrocarbon fluid used in the invention has a weight ratio of isoparaffins to normal paraffins of at least 12:1, preferably at least 15:1, more preferably at least 19:1.

In one embodiment the hydrocarbon fluid used in the invention, relative to the total weight of the hydrocarbon fluid, has a weight content of isoparaffins ranging from 90 to 100% and a weight content of normal paraffins ranging from 0 to 10%, preferably 95 to 100% isoparaffins and 0 to 5% normal paraffins, and more preferably 98 to 100% isoparaffins and 0 to 2% normal paraffins.

Preferably, the hydrocarbon fluid used in the invention, relative to the total weight of the hydrocarbon fluid, has a weight content of naphthenic compounds less than or equal to 1%, preferably less than or equal to 0.5% and more preferably less than or equal to 100 ppm.

In one preferred embodiment, the hydrocarbon fluid used in the invention has a weight content of isoparaffins ranging from 90 to 100%, a weight content of normal paraffins ranging from 0 to 10% and a weight content of naphthenes less than or equal to 1%, relative to the total weight of the hydrocarbon fluid.

More preferably, the hydrocarbon fluid used in the invention has a weight content of isoparaffins ranging from 95 to 100%, a weight content of normal paraffins ranging from 0 to 5% and a weight content of naphthenes less than or equal to 0.5%, relative to the total weight of the hydrocarbon fluid.

Further preferably the hydrocarbon fluid used in the invention has a weight content of isoparaffins ranging from 98% to 100%, a weight content of normal paraffins ranging from 0 to 2% and a weight content of naphthenes less than or equal to 100 ppm, relative to the total weight of the hydrocarbon fluid.

The contents of isoparaffins, normal paraffins and naphthenes can be determined with any method known to skilled persons, e.g. by gas chromatography.

The hydrocarbon fluid used in the invention comprises less than 100 ppm by weight of aromatics, preferably less than 50 ppm by weight of aromatics, more preferably less than 20 ppm by weight of aromatics, relative to the total weight of the hydrocarbon fluid.

The content of aromatics can be determined with any method known to skilled persons e.g. by UV spectrometry.

In one preferred embodiment, the hydrocarbon fluid used in the invention has a weight content of isoparaffins ranging from 90 to 100%, a weight content of normal paraffins ranging from 0 to 10%, a weight content of naphthenes less than or equal to 1% and a weight content of aromatic compounds less than or equal to 100 ppm. More preferably the hydrocarbon fluid used in the invention has a weight content of isoparaffins ranging from 95 to 100%, a weight content of 0 to 5% of normal paraffins, a weight content of naphthenes less than or equal to 0.5% and a weight content of aromatic compounds less than or equal to 50 ppm. More preferably also, the hydrocarbon fluid used in the invention has a weight content of isoparaffins ranging from 95 to 100%, a weight content of normal paraffins of 0 to 5% and a weight content of aromatic compounds less than or equal to 100 ppm. Further preferably, the hydrocarbon fluid used in the invention has a weight content of isoparaffins ranging from 98% to 100%, a weight content of normal paraffins of 0 to 2%, a weight content of naphthenes less than or equal to 100 ppm and a weight content of aromatic compounds less than or equal to 100 ppm.

The hydrocarbon fluid used in the invention also preferably has an extremely low weight content of sulfur-containing compounds, typically less than or equal to 5 ppm, preferably less than or equal to 3 ppm, and more preferably less than or equal to 0.5 ppm, a level that is too low for detection by conventional low-sulfur content analyzers.

The hydrocarbon fluid used in the invention also preferably has a flash point higher than or equal to 110° C., preferably higher than or equal to 120° C. and more preferably higher than or equal to 140° C. according to standard ASTM D93. A high flash point, typically higher than 110° C., particularly overcomes safety problems during storage or transport ensuring lesser flammability of the hydrocarbon fluid.

The hydrocarbon fluid used in the invention also preferably has a vapor pressure at 20° C. lower than or equal to 0.01 kPa.

In one embodiment, the hydrocarbon fluid used in the invention also preferably has a flash point higher than or equal to 110° C. according to standard ASTM D93 and a vapor pressure at 20° C. lower than or equal to 0.01 kPa.

More preferably, the hydrocarbon fluid used in the invention has a flash point higher than or equal to 120° C. and a vapor pressure at 20° C. lower than or equal to 0.01 kPa.

And further preferably, the hydrocarbon fluid used in the invention has a flash point higher than or equal to 140° C. and a vapor pressure at 20° C. lower than or equal to 0.01 kPa.

The hydrocarbon fluid used in the invention additionally and preferably has a kinematic viscosity at 40° C. lower than or equal to 5 cSt, preferably lower than or equal to 4 cSt, measured according to standard ASTM D445.

Preferably, the hydrocarbon fluid used in the invention has an initial boiling point and a final boiling point in the range of 200 to 400° C., preferably 240 to 350° C., more preferably 250 to 340° C.

The boiling points can be determined according to standard ASTM D86.

Preferably, the difference between the final boiling point and the initial boiling point ranges from 10° C. to 80° C., preferably from 20° C. to 50° C.

In one particularly preferred embodiment, the hydrocarbon fluid used in the invention comprises at least 95 weight % of isoparaffins and less than 100 ppm by weight of aromatics, and has an initial boiling and a final boiling point in the range of 200 to 400° C.

In one particularly preferred embodiment, the hydrocarbon fluid used in the invention comprises at least 95 weight % of isoparaffins and less than 100 ppm by weight of aromatics, and has an initial boiling point and a final boiling point in the range of 250 to 340° C.

In one particularly preferred embodiment, the hydrocarbon fluid used in the invention comprises at least 95 weight % of isoparaffins and less than 100 ppm by weight of aromatics, and has an initial boiling and a final boiling point in the range of 200 to 400° C., the difference between the final boiling point and the initial boiling point ranging from 10° C. to 80° C.

In one particularly preferred embodiment, the hydrocarbon fluid used in the invention comprises at least 95 weight % of isoparaffins and less than 100 ppm by weight of aromatics, and has an initial boiling point and a final boiling point in the range of 250 to 340° C., the difference between the final boiling point and the initial boiling point ranging from 10° C. to 80° C.

In one particularly preferred embodiment, the hydrocarbon fluid used in the invention comprises at least 95 weight % of isoparaffins and less than 100 ppm by weight of aromatics, and has an initial boiling point and a final boiling point in the range of 250 to 340° C., the difference between the final boiling point and the initial boiling point ranging from 20° C. to 50° C.

In one embodiment the hydrocarbon fluid used in the invention, relative to the total weight of the hydrocarbon fluid, comprises:
20 to 80 weight % of C15 isoparaffins, and 20 to 80 weight % of C16 isoparaffins, said fluid then possibly comprising isoparaffins having 14 or fewer carbon atoms and/or isoparaffins having 17 or more carbon atoms; or
3 to 20 weight % of C15 isoparaffins, 20 to 70 weight % of C16 isoparaffins, 5 to 40 weight % of C17 isoparaffins, and 5 to 40 weight % of C18 isoparaffins, said fluid optionally comprising isoparaffins having 14 or fewer carbon atoms, and/or isoparaffins having 19 or more carbon atoms; or
5 to 40 weight % of C17 isoparaffins and 60 to 95 weight % of C18 isoparaffins, said fluid optionally comprising isoparaffins having 16 or fewer carbon atoms and/or isoparaffins having 19 or more carbon atoms.

In one particular embodiment the hydrocarbon fluid used in the invention, relative to the total weight of the hydrocarbon fluid, comprises:
30 to 60 weight % of C15 isoparaffins, and 30 to 60 weight % of C16 isoparaffins, said fluid possibly comprising isoparaffins having 14 or fewer carbon atoms and/or isoparaffins having 17 or more carbon atoms; or
5 to 15 weight % of C15 isoparaffins, 30 to 60 weight % of C16 isoparaffins, 10 to 30 weight % of C17 isoparaffins, and 10 to 30 weight % of C18 isoparaffins, said fluid optionally comprising isoparaffins having 14 or fewer carbon atoms and/or isoparaffins having 19 or more carbon atoms; or
10 to 30 weight % of C17 isoparaffins and 60 to 90 weight % of C18 isoparaffins, said fluid optionally comprising isoparaffins having 16 or fewer carbon atoms and/or isoparaffins having 19 or more carbon atoms.

The expression «CX isoparaffins» designates isoparaffins having X carbon atoms.

In one embodiment, the hydrocarbon fluid used in the invention has a biogenic carbon content of at least 90 weight %, preferably at least 95 weight %, more preferably at least 97 weight %, relative to the total weight of the carbon atoms in the hydrocarbon fluid.

Biogenic carbon content can be determined according to standard ASTM D6866 of 2020.

In one embodiment, the hydrocarbon fluid used in the invention comprises 5 to 15 weight % of C15 isoparaffins, 30 to 60 weight % of C16 isoparaffins, 10 to 30 weight % of C17 isoparaffins, and 10 to 30 weight % of C18 isoparaffins, and has an aromatics content of less than 100 ppm by weight relative to the total weight of the hydrocarbon fluid.

In one embodiment, the hydrocarbon fluid used in the invention has an initial boiling point and a final boiling point in the range of 240 to 300° C. and comprises 5 to 15 weight % of C15 isoparaffins, 30 to 60 weight % of C16 isoparaffins, 10 to 30 weight % of C17 isoparaffins and 10 to 30 weight % of C18 isoparaffins, and has an aromatics content of less than 100 ppm by weight, relative to the total weight of the hydrocarbon fluid.

In one embodiment, the hydrocarbon fluid used in the invention comprises 10 to 30 weight % of C17 isoparaffins and 60 to 90 weight % of C18 isoparaffins and has an aromatics content of less than 100 ppm by weight, relative to the total weight of the hydrocarbon fluid.

In one embodiment, the hydrocarbon fluid used in the invention has an initial boiling point and a final boiling point in the range of 260 to 340° C. and comprises 10 to 30 weight % of C17 isoparaffins and 60 to 90 weight % of C18 isoparaffins, and has an aromatics 415 content of less than 100 ppm by weight, relative to the total weight of the hydrocarbon fluid.

In one embodiment, the hydrocarbon fluid used in the invention comprises 5 to 15 weight % of C15 isoparaffins, 30 to 60 weight % of C16 isoparaffins, 10 to 30 weight % of C17 isoparaffins, and 10 to 30 weight % of C18 isoparaffins, and has an aromatics content of less than 100 ppm by weight relative to the total weight of the hydrocarbon fluid, and said fluid has a biogenic carbon content of at least 95 weight % relative to the total weight of the carbon atoms in the hydrocarbon fluid.

In one embodiment, the hydrocarbon fluid used in the invention has an initial boiling point and a final boiling point in the range of 240 to 300° C. and comprises 5 to 15 weight % of C15 isoparaffins, 30 to 60 weight % of C16 isoparaffins, 10 to 30 weight % of C17 isoparaffins and 10 to 30 weight % of C18 isoparaffins, and has an aromatics content of less than 100 ppm by weight relative to the total weight of the hydrocarbon fluid, and said fluid has a biogenic carbon content of at least 95 weight % relative to the total weight of the carbon atoms in the hydrocarbon fluid.

In one embodiment, the hydrocarbon fluid used in the invention comprises 10 to 30 weight % of C17 isoparaffins and 60 to 90 weight % of C18 isoparaffins and has an aromatics content of less than 100 ppm by weight relative to the total weight of the hydrocarbon fluid, and said fluid has a biogenic carbon content of at least 95 weight % relative to the total weight of the carbon atoms in the hydrocarbon fluid.

In one embodiment, the hydrocarbon fluid used in the invention has an initial boiling point and a final boiling point in the range of 260 to 340° C. and comprises 10 to 30 weight % of C17 isoparaffins and 60 to 90 weight % of C18 isoparaffins, and has an aromatics content of less than 100 ppm by weight relative to the total weight of the hydrocarbon fluid, and said fluid has a biogenic carbon content of at least 95 weight % relative to the total weight of the carbon atoms in the hydrocarbon fluid.

In one embodiment, the hydrocarbon fluid used in the invention comprises 5 to 15 weight % of C15 isoparaffins, 30 to 60 weight % of C16 isoparaffins, 10 to 30 weight % of C17 isoparaffins and 10 to 30 weight % of C18 isoparaffins, and has an aromatics content of less than 50 ppm by weight relative to the total weight of the hydrocarbon fluid, and said fluid has a biogenic carbon content of at least 90 weight % relative to the total weight of the carbon atoms in the hydrocarbon fluid.

In one embodiment, the hydrocarbon fluid used in the invention comprises 10 to 30 weight % of C17 isoparaffins and 60 to 90 weight % of C18 isoparaffins, and has an aromatics content of less than 50 ppm by weight relative to the total weight of the hydrocarbon fluid, and said fluid has a biogenic carbon content of at least 90 weight % relative to the total weight of the carbon atoms in the hydrocarbon fluid.

The hydrocarbon fluid used in the invention has 28-day biodegradability of at least 60% measured according to standard OECD 301B. Therefore, typically, the hydrocarbon fluid of the invention can be said to be readily biodegradable.

In contrast, a product will be said to be «inherently biodegradable if it has 28-day biodegradability ranging from 20 to under 60% according to standard OECD 301, e.g. standard OECD 301B.

In one embodiment, the hydrocarbon fluid used in the invention has 28-day biodegradability of at least 70%, preferably at least 80% measured according to standard OECD 301B.

Preferably, the hydrocarbon fluid used in the invention has 28-day biodegradability of at least 60% measured according to standard OECD 306. Standard OECD 306 is more restrictive than standard OECD 301B.

In one particularly preferred embodiment, the hydrocarbon fluid used in the invention comprises at least 95 weight % of isoparaffins and less than 100 ppm by weight of aromatics, and has an initial boiling point and a final boiling point in the range of 200 to 400° C., said hydrocarbon fluid having 28-day biodegradability of at least 60% measured according to standard OECD 301B.

In one particularly preferred embodiment, the hydrocarbon fluid used in the invention comprises at least 95 weight % of isoparaffins and less than 100 ppm by weight of aromatics, and has an initial boiling point and final boiling point in the range of 250 to 340° C., said hydrocarbon fluid having 28-day biodegradability of at least 60% measured according to standard OECD 301B.

In one particularly preferred embodiment, the hydrocarbon fluid used in the invention comprises at least 95 weight % of isoparaffins and less than 100 ppm by weight of aromatics, and has an initial boiling point and a final boiling point in the range of 250 to 340° C., the difference between the final boiling point and initial boiling point ranging from 20° C. to 50° C., said hydrocarbon fluid having 28-day biodegradability of at least 60% measured according to standard OECD 301B.

In one embodiment, the hydrocarbon fluid used in the invention comprises 5 to 15 weight % of C15 isoparaffins, 30 to 60 weight % of C16 isoparaffins, 10 to 30 weight % of C17 isoparaffins and 10 to 30 weight % of C18 isoparaffins, and has an aromatics content of less than 100 ppm by weight relative to the total weight of the hydrocarbon fluid, said hydrocarbon fluid having 28-day biodegradability of at least 60% measured according to standard OECD 301B.

In one embodiment, the hydrocarbon fluid used in the invention comprises 10 to 30 weight % of C17 isoparaffins and 60 to 90 weight % of C18 isoparaffins, and has an aromatics content of less than 100 ppm by weight relative to the total weight of the hydrocarbon fluid, said hydrocarbon fluid having 28-day biodegradability of at least 60% measured according to standard OECD 301B.

In one particularly preferred embodiment, the hydrocarbon fluid used in the invention comprises at least 95 weight % of isoparaffins and less than 50 ppm by weight of aromatics, and has an initial boiling point and a final boiling point in the range of 200 to 400° C., said hydrocarbon fluid having 28-day biodegradability of at least 60% according to standard OECD 301B.

In one particularly preferred embodiment, the hydrocarbon fluid used in the invention comprises at least 95 weight % of isoparaffins and less than 50 ppm by weight of aromatics, and has an initial boiling point and a final boiling point in the range of 250 to 340° C., said hydrocarbon fluid having 28-day biodegradability of at least 60% measured according to standard OECD 301B.

In one particularly preferred embodiment, the hydrocarbon fluid used in the invention comprises at least 95 weight % of isoparaffins and less than 50 ppm by weight of aromatics, and has an initial boiling point and a final boiling point in the range of 250 to 340° C., the difference between the final boiling point and the initial boiling point ranging from 20° C. to 50° C., said hydrocarbon fluid having 28-day biodegradability of at least 60% measured according to standard OECD 301B.

In one embodiment, the hydrocarbon fluid used in the invention comprises 5 to 15 weight % of C15 isoparaffins, 30 to 60 weight % of C16 isoparaffins, 10 to 30 weight % of C17 isoparaffins, and 10 to 30 weight % of C18 isoparaffins, and has an aromatics content of less than 50 ppm by weight relative to the total weight of the hydrocarbon fluid, said hydrocarbon fluid having 28-day biodegradability of at least 60% measured according to standard OECD 301B.

In one embodiment, the hydrocarbon fluid used in the invention comprises 10 to 30 weight % of C17 isoparaffins and 60 to 90 weight % of C18 isoparaffins, and has an aromatics content of less than 50 ppm by weight relative to the total weight of the hydrocarbon fluid, said hydrocarbon fluid having 28-day biodegradability of at least 60% measured according to standard OECD 301B.

### Method for Obtaining the Hydrocarbon Fluid:

The hydrocarbon fluid used in the invention can be obtained in the following manner. The hydrocarbon fluid used in the invention is a hydrocarbon fraction typically derived from the conversion of biomass.

By derived from conversion of biomass, it is meant a hydrocarbon fraction produced from biobased raw materials. The biobased raw materials can be chosen from among vegetable oils, animal fats, fish oils and mixtures thereof.

Preferably, the biobased hydrocarbon fraction is obtained by a method comprising steps of hydrodeoxygenation (HDO) and isomerization (ISO). The hydrodeoxygenation step (HDO) leads to decomposition of the structures of the biological esters or triglyceride constituents, to removal of oxygenated, phosphorus- and sulfur-containing compounds and to hydrogenation of olefin bonds. The product resulting from the hydrodeoxygenation reaction is then isomerized. A fractionating step can preferably follow after the hydrodeoxygenation and isomerization steps. Advantageously, the fractions of interest are subjected to hydrotreatment steps followed by distillation to obtain the specifications of the desired hydrocarbon fluid of the invention.

This HDO/ISO process is implemented on a crude biofeed, also called biomass or biobased raw material, chosen from the group formed by vegetable oils, animal fats, fish oils and mixtures thereof. The suitable biobased raw materials are for example rapeseed oil, canola oil, tallol, sunflower oil, soybean oil, hemp oil, olive oil, flax oil, mustard oil, palm oil, groundnut oil, castor oil, coconut oil, animal fats such as tallow, recycled food fats, raw materials derived from genetic engineering, and biological raw materials produced from microorganisms such as algae and bacteria. Condensation products, esters and other derivatives obtained from crude biomaterials can also be used as raw materials.

Preferably, the biobased raw material is an ester or triglyceride derivative. This material is first subjected to a hydrodeoxygenation step (HDO) to decompose the structure of the constituent esters or triglycerides and to remove oxygenated, phosphorus- and sulfur-containing compounds concomitantly with hydrogenation of the olefin bonds. This hydrodeoxygenation step (HDO) of the biobased raw material is followed by isomerization of the product obtained, leading to branching of the hydrocarbon chain and an improvement in the low-temperature properties of the paraffin.

At the HDO step, hydrogen and the biobased raw material are passed over a catalytic hydrodeoxygenation bed in simultaneous or counterflow. At the HDO step, the pressure and temperature are between 20 and 150 bar and between 20° and 500° C. respectively. Known, conventional hydrodeoxygenation catalysts are used at this step. Optionally, the biobased raw material can be subjected to pre-hydrogenation under mild conditions to prevent secondary reactions of the double bonds before the HDO step. After the hydrodeoxygenation step, the product resulting from the reaction is subjected to an isomerization step (ISO) whereby the hydrogen, the product and optionally a mixture of n-paraffins are passed over isomerization catalytic beds in simultaneous or counterflow. At the ISO step, the pressure and temperature are between 20 and 150 bar and between 20° and 500° C. respectively. Known, conventional isomerization catalysts are used at this step.

Additional secondary processes can also be implemented (such as intermediate mixing, trapping or other like processes).

The product resulting from the HDO/ISO steps can optionally be fractionated to obtain the fractions of interest.

Various HDO/ISO methods are described in the literature. Application WO2014/033762 describes a method comprising a pre-hydrogenation step, a hydrodeoxygenation step (HDO) and an isomerization step operated in counterflow. Patent application EP1728844 describes a method to produce hydrocarbon compounds from a mixture of compounds of vegetable and animal origin. This method comprises a pretreatment step of the mixture to remove contaminants, such as alkali metal salts, followed by a hydrodeoxygenation step (HDO) and isomerization step. Patent application EP2084245 describes a method to produce a hydrocarbon mixture which can be used as diesel oil or in a diesel oil composition, by hydrodeoxygenation of a biomixture containing fatty acid esters optionally in a mixture with free fatty acids e.g. vegetable oils such as sunflower oil, rapeseed oil, canola oil, palm oil or pine oil, followed by hydroisomerization on specific catalysts. Patent application EP2368967 describes said method and the product obtained with this method.

Advantageously, the biobased raw material contains less than 15 ppm of sulfur, preferably less than 8 ppm, more preferably less than 5 ppm and further preferably less than 1 ppm according to standard EN ISO 20846. Ideally, the feed does not comprise sulfur as biobased raw material.

The deoxygenated and isomerized feed resulting from the HDO/ISO process is then hydrogenated, optionally after being fractionated to obtain a desired boiling range.

Preferably, the hydrogenation step is a catalytic hydrogenation step at a temperature of 80 to 180° C. and at a pressure of 50 to 160 bar of a biobased, deoxygenated, and isomerized feed (or fraction).

The hydrogen used in the hydrogenation unit is typically highly pure hydrogen. By highly pure it is meant hydrogen having purity higher than 99% for example, even if other grades can also be used.

The hydrogenation step is performed by means of catalysts. Standard hydrogenation catalysts can either be solid or supported and may comprise the following metals: nickel, platinum, palladium, rhenium, rhodium, nickel tungstate, nickel-molybdenum, molybdenum, cobalt-molybdenum. The supports can be silica, alumina, silica-alumina, or zeolites.

One preferred catalyst is nickel on an alumina support having a specific surface area preferably varying from 100 to 200 m²/g of catalyst, or a solid nickel catalyst. The hydrogenation conditions are typically the following:
Pressure: 50 to 160 bar, preferably 80 to 150 bar and more preferably 90 to 120 bar;
Temperature: 80 to 180° C., preferably 120 to 160° C., and more preferably 150 to 160° C.;
Liquid Hourly Space Velocity (LHSV): 0.2 to 5 hr−1, preferably 0.4 to 3 hr−1 and more preferably 0.5 to 0.8 hr−1;
Hydrogen treatment rate: adapted to the above-mentioned conditions and possibly ranging up 200 Nm3/tonnes of feed to be treated.

The temperature in the reactors is typically between 15° and 160° C. with a pressure of about 100 bar, while the liquid hourly space velocity is about 0.6 hr−1 with a treatment rate adapted according to the quality of the feed to be treated and the parameters of the first hydrogenation reactor.

Hydrogenation can take place in one or more reactors in series. The reactors may comprise one or more catalytic beds. The catalytic beds are generally fixed catalytic beds.

The hydrogenation process preferably comprises two or three reactors, preferably three reactors and is preferably conducted in three reactors in series.

The first reactor allows trapping of sulfur-containing compounds and hydrogenation of essentially all unsaturated compounds up to about 90 weight % of the aromatic compounds. The product resulting from the first reactor contains substantially no sulfur compound. At the second stage i.e. in the second reactor, hydrogenation of the aromatics is continued and up to 99 weight % of aromatics are consequently hydrogenated.

The third stage in the third reactor is a finishing stage allowing aromatic contents of less than 100 ppm to be obtained, preferably less than 50 ppm, more preferably less than 20 ppm.

It is possible to use a reactor comprising two, three or more catalytic beds. The catalysts can be used in varying quantities or in essentially equal quantities in each reactor; for example, for three reactors, the quantities as a function of weight can be 0.05-0.5/0.10-0.70/0.25-0.85, preferably 0.07-0.25/0.15-0.35/0.4-0.78 and more preferably 0.10-0.20/0.20-0.32/0.48-0.70.

It is also possible to use one or two hydrogenation reactors instead of three.

IIt is also possible that the first reactor could be a twin reactor used in alternance. This operating mode particularly allows facilitated loading and unloading of the catalysts: when the first reactor comprises the first-saturated catalyst (substantially all the sulfur is trapped on and/or in the catalyst), it must often be changed.

A single reactor can also be used in which two, three or more catalytic beds are installed.

It may be necessary to insert quench boxes in the recycle system or between the reactors to cool the effluents from one reactor or another or from one catalytic bed to another, to control the temperatures and hydrothermal equilibrium of each reaction. In one preferred embodiment, there are no cooling or quench intermediates.

In one embodiment, the product resulting from the process and/or the separated gases are at least partially recycled in the feed system of the hydrogenation reactors. This dilution contributes towards maintaining the exothermicity of the reaction within controlled limits, in particular at the first stage. Recycling further permits exchange of heat before the reaction and therefore better control over temperature.

The effluent from the hydrogenation unit chiefly contains the hydrogenated product and hydrogen. Flash separators are used to separate the gas phase effluents, mainly residual hydrogen, from the liquid phase mainly the hydrogenated hydrocarbon fractions. The process can be conducted using three flash separators, one at high pressure, one at intermediate pressure and one at low pressure very close to atmospheric pressure.

The gaseous hydrogen collected at the top of the flash separators can be recycled back to the feed system of the hydrogenation unit or at different levels in the hydrogenation units between the reactors.

In one embodiment, the end product is separated at atmospheric pressure. It is then directly fed into a vacuum fractionating unit. Preferably, fractionation is performed at a pressure of between 10 and 50 mbar, and more preferably at about 30 mbar.

Fractionation can be conducted so that it is possible, simultaneously, to withdraw various hydrocarbon fluids from the fractionating column and so that the boiling temperature thereof can be predetermined.

By adapting the feed via the initial and final boiling points thereof, the hydrogenation reactors, separators and fractionating unit can therefore be connected directly without the need to use intermediate tanks. This integration of hydrogenation and fractionation allows optimized thermal integration associated with a reduction in the number of items of equipment and energy savings.

Therefore, in one embodiment of the invention, the hydrocarbon fluid used in the invention is obtained with a method comprising a catalytic hydrogenation step of a biomass that is hydrodeoxygenated and hydroisomerized, said hydrogenation step being performed at a temperature ranging from 80 to 180° C. and at a pressure of 50 to 160 bar, preferably at a temperature ranging from 120 to 160° C. and at a pressure ranging from 80 to 150 bar, more preferably at a temperature ranging from 150 to 160° C. and at a pressure ranging from 90 to 120 bar.

In one particular embodiment, the hydrocarbon fluid used in the invention is obtained with a method comprising:
a hydrodeoxygenation step followed by a hydroisomerization step of a biomass, to obtain a hydrodeoxygenated and hydroisomerized biomass,
a catalytic hydrogenation step of the hydrodeoxygenated and hydroisomerized biomass, said hydrogenation step being performed at a temperature ranging from 80 to 180° C. and at a pressure of 50 to 160 bar, preferably at a temperature ranging from 120 to 160° C. and pressure ranging from 80 to 150 bar, more preferably at a temperature ranging from 150 to 160° C. and at a pressure ranging from 90 to 120 bar,

The biomass preferably being chosen from among vegetable oils, animal fats, fish oils and mixtures thereof.

The hydrocarbon fluid used in the invention ideally results from the treatment of biobased raw materials. The term «biogenic carbon» or «biobased carbon» indicates that the carbon is of natural origin and is derived from a biomaterial as indicated below. The biobased carbon content, biogenic carbon content and biomaterial content are expressions indicating the same value. A material from a renewable resource or biomaterial is an organic material in which the carbon is derived from atmospheric CO₂ recently fixed (on a human scale) via photosynthesis. A biomaterial (Carbon 100% biobased) has a ¹⁴C/¹²C isotope ratio higher than 10⁻¹², typically about 1.2×10⁻¹², whilst the ratio for a fossil material is zero. Isotopic ¹⁴C formed in the atmosphere is integrated via photosynthesis on a time scale of no more than a few tens of years. The half-life of ¹⁴C is 5730 years. Therefore materials derived from photosynthesis, namely plants in general, necessarily have a maximum content of ¹⁴C isotope.

### Additives

In one embodiment the composition used as cooling fluid, in addition to the hydrocarbon fluid, comprises one or more additives.

Among the additives able to be used, mention can be made of antioxidants, flame retardants and mixtures thereof.

In one embodiment, the composition comprises at least one flame retardant additive. The flame retardant additive can be chosen from among halogenated compounds, phosphorus compounds, metal hydroxides and mixtures thereof.

In one embodiment, the flame retardant additive meets formula (I):

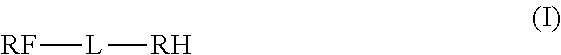

where:
RF is a hydrocarbon group, in particular having 1 to 22, preferably 1 to 20, more preferably 1 to 16 carbon atoms,
RH is a hydrocarbon group, in particular having 1 to 22, preferably 1 to 20, more preferably 1 to 16 carbon atoms, and
L is a linker chosen from the following groups: —CH₂—, —CH═CH—, —O—, —S— or —PO₄—,

RF and/or RH possibly also comprising at least one element chosen from among the elements of the halogen class, such as preferably fluorine, bromine, and/or chlorine.

In one embodiment, the composition is free of perfluorooctyl bromide.

If used in the composition, the flame retardant(s) preferably represent from 0.01 to 20 weight % of the weight of the composition, preferably 1 to 10 weight % of the weight of the composition.

In one embodiment, the composition comprises at least one antioxidant additive. The antioxidant additive generally allows delayed degradation of the composition when in use. This degradation can particularly translate as the formation of deposits, the presence of sludge or an increase in the viscosity of the composition.

Antioxidant additives particularly act as radical inhibitors or hydroperoxide decomposers. Among antioxidants routinely used, mention can be made of antioxidant additives of phenolic type, antioxidant additives of amine type, sulfur-phosphorus antioxidant additives. Some of these antioxidant additives, for example those containing sulfur and phosphorus can generate ash. Phenolic antioxidant additives can be ash-free or can be in the form of neutral or basic metal salts. The antioxidant additives can particularly be chosen from among sterically hindered phenols, the esters of sterically hindered phenols, and sterically hindered phenols comprising a thioether bridge, diphenylamines, diphenylamines substituted by at least one C₁-C₁₂ alkyl group, and mixtures thereof.

In one embodiment, the sterically hindered phenols are chosen from among compounds comprising a phenol group in which at least one vicinal carbon of the carbon atoms carrying the alcohol function is substituted by at least one C₁-C₁₀ alkyl group, preferably C₁-C₆ alkyl group, preferably a C₄ alkyl group, preferably a tert-butyl group.

Amine compounds are another class of antioxidant additives able to be used, optionally in combination with the phenolic antioxidant additives. Examples of amine compounds are aromatic amines e.g. aromatic amines of formula NR⁴R⁵R⁶ where R⁴ is an optionally substituted aliphatic group or aromatic group, R⁵ is an optionally substituted aromatic group, R⁶ is a hydrogen atom, an alkyl group, aryl group or group of formula R⁷S(O)zR⁸ where R⁷ is an alkylene group or alkenylene group, R⁸ is an alkyl group, alkenyl group or aryl group, and z is 0, 1 or 2.

Sulfurized alkyl phenols or the alkali or alkaline-earth metal salts thereof can also be used as antioxidant additives.

Another class of antioxidant additives includes copper-containing compounds, e.g. copper thio- or dithio-phosphates, the salts of copper and carboxylic acids, copper dithiocarbamates, sulfonates, phenates, and acetylacetonates. The salts of copper I and II, the salts of succinic acid or anhydride can also be used.

If used in the composition, the antioxidant(s) preferably represent 0.01 to 3 weight % of the weight of the composition, preferably 0.05 to 2 weight % of the weight of the composition.

### Use of the Hydrocarbon Fluid or of the Composition:

The hydrocarbon fluid or the composition are used as cooling fluid via direct immersion, in particular via direct immersion of data center equipment.

Preferably, cooling is cooling via single-phase direct immersion. In other words, typically the hydrocarbon fluid (or the composition) does not undergo a phase change during the cooling process.

Examples of equipment in a data center are servers, computers particularly including microprocessors.

In one embodiment the invention concerns the use as cooling fluid, via direct immersion, of a composition comprising 80 to 100 weight % of a hydrocarbon fluid relative to the total weight of the composition, said hydrocarbon fluid comprising at least 90 weight % of a hydrocarbon fluid comprising at least 90 weight % of isoparaffins and less than 50 ppm by weight of aromatics relative to the total weight of the hydrocarbon fluid, said hydrocarbon fluid having 28-day biodegradability measured according to standard OECD 301B higher than or equal to 60%, said hydrocarbon fluid having an initial boiling point and a final boiling point in the range of 200 to 400° C., preferably 240 to 350° C., more preferably 250 to 340° C.

In one embodiment the invention concerns the use as cooling fluid, via direct immersion, of a composition comprising 95 to 100 weight % of a hydrocarbon fluid relative to the total weight of the composition, said hydrocarbon fluid comprising at least 90 weight % of a hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%, said hydrocarbon fluid having an initial boiling point and a final boiling point in the range of 200 to 400° C., preferably 240 to 350° C., more preferably 250 to 340° C.

In one embodiment, the invention concerns the use as cooling fluid, via direct immersion, of a composition comprising 98 to 100 weight % of a hydrocarbon fluid relative to the total weight of the composition, said hydrocarbon fluid comprising at least 90 weight % of a hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%, said hydrocarbon fluid having an initial boiling point and a final boiling point in the range of 200 to 400° C., preferably 240 to 350° C., more preferably 250 to 340° C.

In one embodiment the invention concerns the use as cooling fluid, via direct immersion of an item of equipment in a data center, of a composition comprising 80 to 100 weight % of a hydrocarbon fluid relative to the total weight of the composition, said hydrocarbon fluid comprising at least 90 weight % of a hydrocarbon fluid comprising at least 90 weight % of isoparaffins and less than 50 ppm by weight of aromatics relative to the total weight of the hydrocarbon fluid, said hydrocarbon fluid having 28-day biodegradability higher than or equal 60% measured according to standard OECD 301B.

### Cooling System

A further subject of the present invention is a system for cooling at least one item of equipment via direct immersion, comprising:
a bath comprising the composition defined in the present invention,
said at least one item of equipment partially or fully immersed in the composition.

Immersion can be full immersion if the total volume of the item of equipment is immersed in the hydrocarbon fluid.

Immersion can be partial if the total volume of the item of equipment is not immersed in the hydrocarbon fluid, but only a part thereof.

Preferably, the item of equipment to be cooled is equipment in a data center e.g. a server or a computer.

The composition comprising the hydrocarbon fluid can be static or circulating within the cooling system.

The cooling system may additionally comprise a heat exchange system wherein the cooling liquid, heated by the equipment in the bath, is cooled before being returned to the bath.

In one embodiment, the hydrocarbon fluid or the composition can then be placed in circulation between the bath comprising at least one item of equipment to be cooled and the heat exchange system.

The heat exchange system can be connected to a water or air circuit, the water or air allowing cooling of the hydrocarbon fluid or composition before they are returned to the bath, to ensure the cooling function thereof.

Putting the cooling fluid in circulation can be made by a pumping system.

The heat recovered from the composition comprising the hydrocarbon fluid at the time of heat exchange can optionally be recovered and used to heat a building for example.

### Cooling Method

A further subject of the present invention is a method for cooling at least one item of equipment via direct immersion, comprising a step of fully or partially immersing said at least one item of equipment in the composition defined in the present invention.

Typically, the composition is placed in a bath and the item of equipment is fully or partially immersed in the composition within said bath.

Preferably, the item of equipment to be cooled is equipment in a data center e.g. a server or a 0850computer.

The cooling method of the invention can be implemented in the cooling system of the invention.

The cooling method of the invention may additionally comprise a step to cool the composition heated by immersion of equipment in the bath. This cooling step of the composition can be implemented by means of a heat exchanger external to the bath and with a water or air circuit. In one embodiment, after the cooling step of the composition, the method of the invention may additionally comprise a step to recover the heat derived from the composition, said recovered heat optionally being used to heat a building for example.

### EXAMPLES

In the remainder of the present description, examples are given to illustrate the invention that are in no manner intended to limit the scope thereof.

Three hydrocarbon fluids were prepared following the method described in the present invention, by HDO/ISO of a biomass followed by a hydrogenation step.

Table 1 groups together the physicochemical properties of the hydrocarbon fluids.

TABLE 1

| | Fluid 1 | Fluid 2 | Fluid 3 |
|---|---|---|---|
| % iso paraffins (weight/ | 98.9 | 95.1 | 96.2 |
| weight) | | | |
| % n-paraffins (weight/weight) | 1.1 | 4.9 | 3.8 |
| % naphthenes (weight/weight) | 0 | 0 | 0 |
| Aromatics (ppm) | <20 | <20 | <20 |
| Sulfur (ppm) | 0.1 | 0.1 | 0.11 |
| C13 (iso) | 0.66 | 0 | 0 |
| C14 (iso) | 4.15 | 0.12 | 0 |
| C15 (iso) | 48.35 | 11.45 | 0 |
| C16 (iso) | 42.80 | 47.89 | 1.58 |
| C17 (iso) | 2.52 | 18.57 | 14.17 |
| C18 (iso) | 0.38 | 17.07 | 79.69 |
| C19 (iso) | 0 | 0 | 0.12 |
| C20 (iso) | 0 | 0 | 0.38 |
| C27 (iso) | 0 | 0 | 0.29 |
| Quantity of biogenic carbon | 97 | 97 | 98 |
| (%) | | | |
| Initial boiling point (° C.) | 247.0 | 259.5 | 293.6 |
| 5% boiling point (° C.) | 255.7 | 270.2 | 296.7 |
| 50% boiling point (° C.) | 258.9 | 274.5 | 298.5 |
| 95% boiling point (° C.) | 266.8 | 286.4 | 305.3 |
| Final boiling point (° C.) | 269.0 | 287.5 | 324.1 |
| 28-day biodegradability (%) | 89 | 89 | 89 |
| Refractive index at 20° C. | 1.4336 | 1.4357 | 1.4394 |
| Density at 15° C. (kg/m3) | 776.4 | 780.3 | 787.2 |
| Flash point (° C.) | 115 | 125 | 149 |
| Pour point (° C.) | −81 | −60 | −45 |
| Kinematic viscosity at 40° C. | 2.49 | 2.94 | 3.87 |
| (cSt) | | | |
| Vapor pressure at 20° C. | <0.01 | <0.01 | <0.01 |
| (kPa) | | | |
| Specific heat (at ° C. in J/ | 30.3/2154 | 31.3/2202 | 31.3/2185 |
| (kg · K)) | 74.8/2336 | 74.8/2324 | 89.7/2377 |
| | 129.2/2540 | 129.2/2503 | 158.9/2695 |
| Thermal conductivity (at ° C. | 28/0.130 | 27/0.135 | 23/0.138 |
| in W/(m · K)) | 73/0.125 | 73/0.128 | 88/0.137 |
| | 128/0.124 | 127/0.126 | 158/0.127 |

The following standards and methods were used to measure the above properties:
flash point EN ISO 2719;
density at 15° C.: EN ISO 1185;
pour point: EN ISO 3016;
viscosity at 40° C.: EN ISO 3104;
boiling point: ASTM D86;
biodegradability: OECD 301B method;
pour point: ASTM D5950.

Specific heat was measured using a DSC calorimeter (DSC NETZSCH 204 Phoenix) conforming to standards ISO 113587, ASTM E1269, ASTM E968, ASTM E793, ASTM D3895, ASTM D3417, ASTM D3418, DIN 51004, DIN 51007, and DIN 53765.

Thermal conductivity was determined with the following method:

Apparatus composed of two aluminum tubes, one inner and one outer, was used. The fluid to be measured is placed in the annular space between the two tubes. A pulse energy (Dirac type) is applied to the inner tube and the temperature is measured on the outer tube, allowing a thermogram to be obtained.

Knowing thermal diffusivity, the density and specific heat of the two layers of the two aluminum tubes as a function of temperature, and knowing the density and specific heat of the fluid to be analyzed, it is possible to deduce therefrom the thermal conductivity of the fluid as a function of temperature.

The apparatus is first calibrated with a reference sample, SERIOLA 1510 (heat transfer fluid) at different temperatures. The different thermal properties were previously measured separately.

The sample (fluid to be measured) is mixed and loaded (using a syringe) into the annular space between the two tubes. The loaded apparatus is then placed in a temperature-controlled chamber.

For each temperature measurement, the procedure is as follows. The sample is stabilized at a given temperature. Light flashes are applied to the inner surface of the inner tube and the rise in temperature of the outer surface of the outer tube is recorded over time.

On the basis of the mean values obtained with at least 3 measurements at each given temperature, the thermal conductivity can be calculated.

Tests were conducted to compare the oxidation stability properties of the fluid of the invention with a fluid according to document WO2022/038313.

The tested fluids were the following:
Fluid 3 in Table 1,
Fluid CC1 obtained by HDO/ISO of a biomass such as described in document WO2022/038313, having a boiling range of 190-310° C., isoparaffin content of 95 weight % and aromatic content of 600 ppm.
The tests were conducted on compositions comprising 99.5 weight % of fluid (either Fluid 3 or Fluid CC1) and 0.5 weight % of BHT as antioxidant, applying standard ASTM D2272 (RPVOT test).

The results are the following:

$$- Fluid 3 = 465 min ,$$

$$- Fluid CC 1 = 315 min .$$

These results show that the fluid of the invention exhibits much better oxidation stability than the prior art fluid.

To summarize, the hydrocarbon fluid displays excellent thermal properties and has a very low content of aromatics meaning that it is particularly advantageous for cooling equipment in data centers via direct immersion. The very low aromatics content improves ageing, provides better resistance to ageing, this being most useful for this type of application where the same fluid can be used for 5 years, even 10 years, and reduces and even eliminates the irritant nature of the fluid, thereby improving safety for operators of the fluid.

1. A method of cooling, the method comprising a step of using a composition as cooling fluid, via direct immersion, the composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%.

2. The method according to claim 1, wherein the composition is used as cooling fluid via direct immersion of an item of equipment in a data center.

3. The method according to claim 1, wherein the hydrocarbon fluid, relative to the total weight of the hydrocarbon fluid, comprises:
at least 95 weight % of isoparaffins, and/or
at most 5 weight % of normal paraffins, and/or
at most 1 weight % of naphthenes, and/or
less than 50 ppm by weight of aromatics.

4. The method according to claim 1, wherein the hydrocarbon fluid has:
a flash point higher than or equal to 110° C., according to standard ASTM D93; and/or
a kinematic viscosity at 40° C. lower than or equal to 5 cSt; and/or
an initial boiling point and a final boiling point in the range of 200 to 400° C.; and/or
a difference between the final boiling point and the initial boiling point ranging from 10° C. to 80° C.

5. The method according to claim 1, wherein the hydrocarbon fluid, relative to the total weight of the hydrocarbon fluid, comprises:
30 to 60 weight % of C15 isoparaffins and 30 to 60 weight % of C16 isoparaffins; or
5 to 15 weight % of C15 isoparaffins, 30 to 60 weight % of C16 isoparaffins, 10 to 30 weight % of C17 isoparaffins, and 10 to 30 weight % of C18 isoparaffins; or
10 to 30 weight % of C17 isoparaffins and 60 to 90 weight % of C18 isoparaffins.

6. The method according to claim 1, wherein the composition comprises 100 weight % of the cooling fluid.

7. The method according to claim 1, wherein the composition further comprises, relative to the total weight of the composition, from 0.01 to 20 weight % of additives.

8. A cooling system via direct immersion, comprising:
a bath comprising a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%,
at least one item of equipment to be cooled, partially or fully immersed in the composition.

9. The cooling system according to claim 8, wherein the item of equipment to be cooled is equipment in a data center.

10. The cooling system according to claim 8, wherein the hydrocarbon fluid has one or more of the following features:
a) the hydrocarbon fluid, relative to the total weight of the hydrocarbon fluid, comprises:
at least 95 weight % of isoparaffins, and/or
at most 5 weight % of normal paraffins, and/or
at most 1 weight % of naphthenes, and/or
less than 50 ppm by weight of aromatics;
b) the hydrocarbon fluid has:
a flash point higher than or equal to 110° C., according to standard ASTM D93; and/or
a kinematic viscosity at 40° C. lower than or equal to 5 cSt; and/or
an initial boiling point and a final boiling point in the range of 200 to 400° C.; and/or
a difference between the final boiling point and the initial boiling point ranging from 10° C. to 80° C.;
c) the hydrocarbon fluid, relative to the total weight of the hydrocarbon fluid, comprises:
30 to 60 weight % of C15 isoparaffins and 30 to 60 weight % of C16 isoparaffins; or
5 to 15 weight % of C15 isoparaffins, 30 to 60 weight % of C16 isoparaffins, 10 to 30 weight % of C17 isoparaffins, and 10 to 30 weight % of C18 isoparaffins; or
10 to 30 weight % of C17 isoparaffins and 60 to 90 weight % of C18 isoparaffins.

11. The cooling system according to claim 8, wherein the composition comprises 100 weight % of the cooling fluid.

12. A cooling method via direct immersion, comprising a step of fully or partially immersing at least one item of equipment to be cooled in a composition comprising 80 to 100 weight % of a hydrocarbon fluid relative to the total weight of the composition, said hydrocarbon fluid comprising at least 90 weight % of isoparaffins and less than 100 ppm by weight of aromatics relative to the total weight of the hydrocarbon fluid, said hydrocarbon fluid having 28-day biodegradability measured according to standard OECD 301B higher than or equal to 60%.

13. The cooling method according to claim 12, wherein the item of equipment to be cooled is equipment in a data center.

14. The cooling method according to claim 12, wherein the hydrocarbon fluid has one or more of the following features:
a) the hydrocarbon fluid, relative to the total weight of the hydrocarbon fluid, comprises:
at least 95 weight % of isoparaffins, and/or
at most 5 weight % of normal paraffins, and/or
at most 1 weight % of naphthenes, and/or
less than 50 ppm by weight of aromatics;
b) the hydrocarbon fluid has:
a flash point higher than or equal to 110° C., according to standard ASTM D93; and/or
a kinematic viscosity at 40° C. lower than or equal to 5 cSt; and/or
an initial boiling point and a final boiling point in the range of 200 to 400° C.; and/or
a difference between the final boiling point and the initial boiling point ranging from 10° C. to 80° C.;
c) the hydrocarbon fluid, relative to the total weight of the hydrocarbon fluid, comprises:
30 to 60 weight % of C15 isoparaffins and 30 to 60 weight % of C16 isoparaffins; or
5 to 15 weight % of C15 isoparaffins, 30 to 60 weight % of C16 isoparaffins, 10 to 30 weight % of C17 isoparaffins, and 10 to 30 weight % of C18 isoparaffins; or
10 to 30 weight % of C17 isoparaffins and 60 to 90 weight % of C18 isoparaffins.

15. The cooling method according to claim 12, wherein the composition comprises 100 weight % of the cooling fluid.

16. The cooling method according to claim 12, wherein the composition further comprises, relative to the total weight of the composition, from 0.01 to 20 weight % of additives.

17. The method according to claim 1, wherein the composition further comprises, relative to the total weight of the composition, from 0.01 to 20 weight % of additives chosen from among antioxidants, flame retardants and mixture thereof.

18. The cooling system according to claim 8, wherein the composition further comprises, relative to the total weight of the composition, from 0.01 to 20 weight % of additives.
